(19) United States
(12) Patent Application Publication
(10) Pub. No.: US 2025/0105231 A1
(43) Pub. Date: Mar. 27, 2025

(54) SEMICONDUCTOR PACKAGE

(71) Applicant: Samsung Electronics Co., Ltd., Suwon-si (KR)

(72) Inventors: Junghoon KANG, Suwon-si (KR); Daegon KIM, Suwon-si (KR)

(73) Assignee: Samsung Electronics Co., Ltd., Suwon-si, Gyeonggi-do (KR)

(21) Appl. No.: 18/772,409

(22) Filed: Jul. 15, 2024

(30) Foreign Application Priority Data
Sep. 25, 2023 (KR) 10-2023-0128485

(51) Int. Cl. H01L 25/16; H01L 23/00; H01L 23/31; H01L 23/48; H01L 23/498

(52) U.S. Cl. CPC H01L 25/167; H01L 23/3128; H01L 23/481; H01L 23/49827; H01L 23/49838; H01L 24/16; H01L 2224/16227

(57) ABSTRACT

A semiconductor package including a package substrate defining a groove extending from an upper surface of the package substrate into the package substrate; a photonic integrated circuit (PIC) chip inside the groove of the package substrate; an interposer above the PIC chip and the package substrate, the interposer including a core substrate; an electronic integrated circuit (EIC) chip inside the interposer; and a semiconductor chip above the interposer. The interposer defines a cavity extending from an upper surface of the core substrate to a lower surface of the core substrate, and the EIC chip is inside the cavity of the core substrate.

### CROSS-REFERENCE TO RELATED APPLICATION

This application is based on and claims priority under 35 U.S.C. § 119 to Korean Patent Application No. 10-2023-0128485, filed on Sep. 25, 2023, in the Korean Intellectual Property Office, the disclosure of which is incorporated by reference herein in its entirety.

### BACKGROUND

The present disclosure relates to semiconductor packages, and more particularly, to semiconductor packages including a photonic integrated circuit (PIC) chip, and a method of manufacturing the semiconductor packages.

To improve the functionality of electronic devices and integrate components thereof, the merits of semiconductor packages have increasingly been utilized. In a semiconductor package, various integrated circuits, such as memory chips or logic chips, may be mounted on a package substrate. Recently, in an environment in which data traffic is increasing in data centers and communication infrastructure, research on a semiconductor package including a PIC chip has been continuously conducted.

### SUMMARY

Example embodiments of the inventive concepts provide a semiconductor package having a photonic integrated circuit (PIC) chip mounted thereon without a separate printed circuit board (PCB).

Example embodiments of the inventive concepts also provide a semiconductor package having high integration density.

Example embodiments of the inventive concept also provide a semiconductor package having short signal distance between a PIC chip and an electronic integrated circuit (EIC) chip.

The objectives of the inventive concepts are not limited as described above, and other objectives will be clearly understood by those skilled in the art from the following description.

Example embodiments of the inventive concepts provide a semiconductor package including a package substrate defining a groove extending from an upper surface of the package substrate into the package substrate; a PIC chip inside the groove of the package substrate; an interposer above the PIC chip and the package substrate, the interposer including a core substrate; an EIC chip inside the interposer; and a semiconductor chip above the interposer. The interposer defines a cavity extending from an upper surface of the core substrate to a lower surface of the core substrate, and the EIC chip is inside the cavity of the core substrate.

Example embodiments of the inventive concepts further provide a semiconductor package including a package substrate defining at least one groove extending from an upper surface of the package substrate into the package substrate; at least one PIC chip inside the at least one groove of the package substrate; an interposer above the at least one PIC chip and the package substrate, the interposer including a core substrate; at least one EIC chip inside the interposer; and a semiconductor chip above the interposer. The interposer defines at least one cavity extending from an upper surface of the core substrate to a lower surface of the core substrate, and the at least one EIC chip is inside the at least one cavity of the core substrate.

Example embodiments of the inventive concepts still further provide a semiconductor package including a package substrate defining a groove extending from an upper surface of the package substrate into the package substrate; a PIC chip inside the groove of the package substrate, the PIC chip including an optical-electrical conversion unit; an interposer above the PIC chip and the package substrate, the interposer including a core substrate, an upper redistribution structure, and a lower redistribution structure, the upper redistribution structure being on an upper surface of the core substrate, and the lower redistribution structure being on a lower surface of the core substrate; an EIC chip inside the interposer, the EIC chip including a substrate and a through via, the substrate having an active surface and an inactive surface facing the active surface, and the through via extending from the inactive surface of the substrate to the active surface of the substrate; and a semiconductor chip above the interposer. The interposer defining a cavity extending from the upper surface of the core substrate to the lower surface of the core substrate. The EIC chip is inside the cavity of the core substrate and the active surface of the substrate faces the PIC chip.

### BRIEF DESCRIPTION OF THE DRAWINGS

Embodiments will be more clearly understood from the following detailed description taken in conjunction with the accompanying drawings in which:

FIG. 1 is a schematic perspective view of a semiconductor package according to some example embodiments;

FIG. 2 is a schematic plan view of the semiconductor package of FIG. 1;

FIG. 3 is a schematic cross-sectional view of the semiconductor package of FIG. 1, taken along line A1-A1′ of FIG. 2;

FIG. 4 is a schematic enlarged view of a portion of the semiconductor package of FIG. 2;

FIG. 5 is a schematic cross-sectional view of a semiconductor package according to some example embodiments, taken along line A1-A1′ of FIG. 2;

FIG. 6 is a schematic cross-sectional view of a semiconductor package according to some example embodiments, taken along line A1-A1′ of FIG. 2;

FIG. 7 is a schematic plan view of a semiconductor package according to some example embodiments;

FIG. 8 is a schematic cross-sectional view of the semiconductor package of FIG. 7, taken along line B1-B1′ of FIG. 7;

FIG. 9 is a schematic plan view of a semiconductor package according to some example embodiments;

FIG. 10 is a schematic cross-sectional view of the semiconductor package of FIG. 9, taken along line B2-B2′ of FIG. 9;

FIG. 11 is a schematic perspective view of a semiconductor package according to some example embodiments;

FIG. 12 is a schematic plan view of the semiconductor package of FIG. 11;

FIG. 13 is a schematic cross-sectional view of the semiconductor package of FIG. 11, taken along line A2-A2′ of FIG. 12; and

FIG. 14 is a schematic cross-sectional view of a semiconductor package according to some example embodiments, taken along line A2-A2′ of FIG. 12.

### DETAILED DESCRIPTION

As the inventive concepts allow for various changes and numerous embodiments, particular embodiments will be illustrated in the drawings and described in detail in the written description. However, this is not intended to limit the inventive concepts to particular modes of practice.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

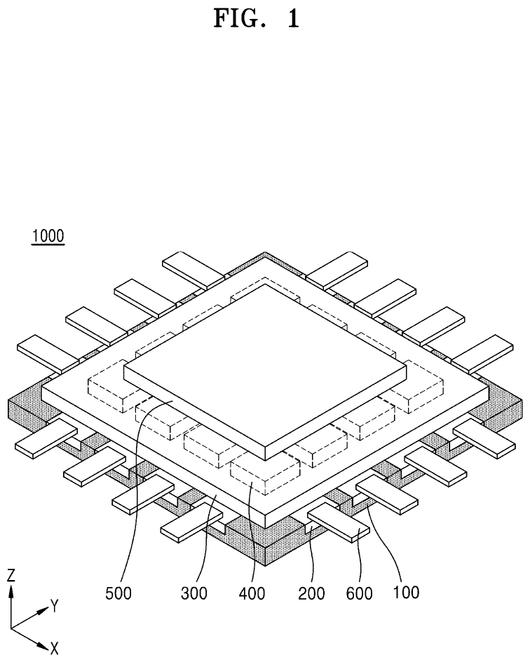

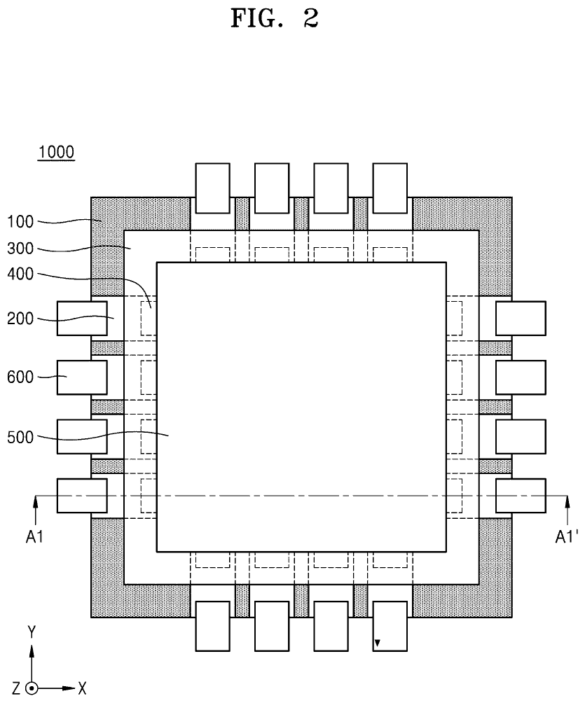

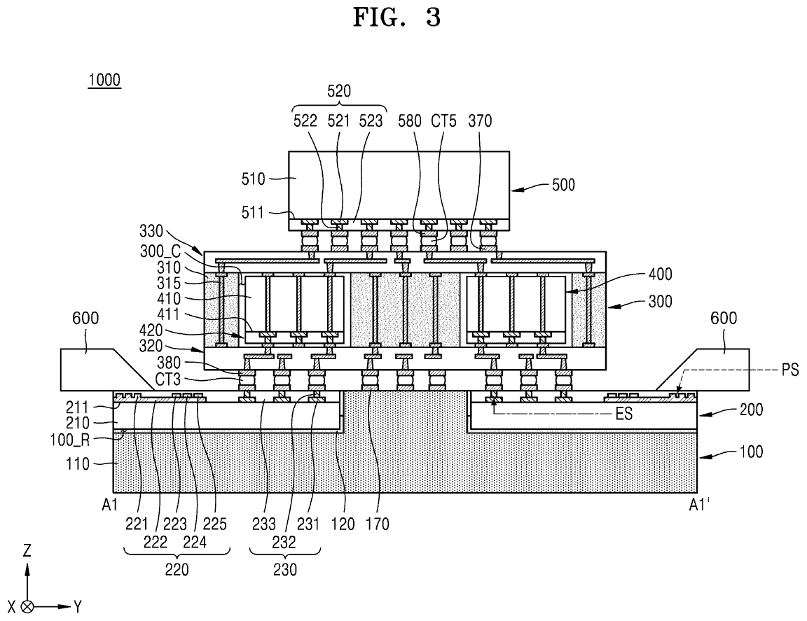

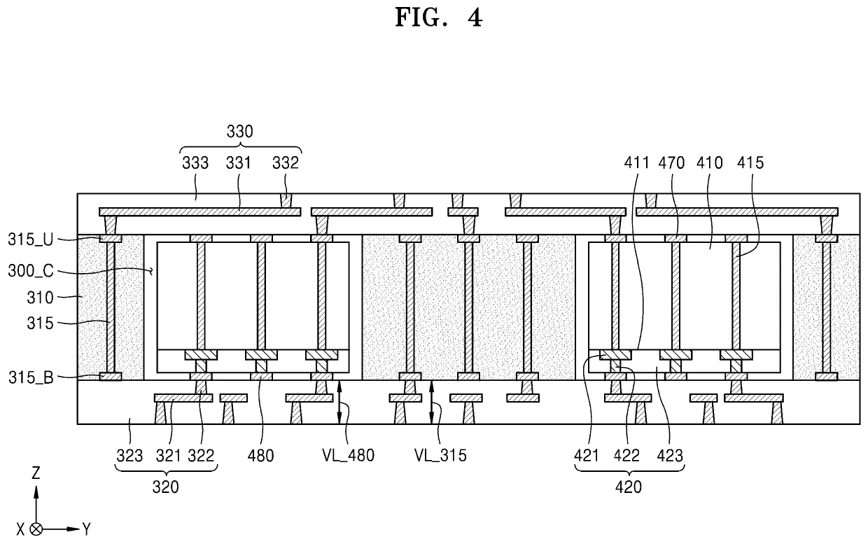

FIG. 1 is a schematic perspective view of a semiconductor package 1000 according to some example embodiments. FIG. 2 is a schematic plan view of the semiconductor package 1000 of FIG. 1. FIG. 3 is a schematic cross-sectional view of the semiconductor package 1000 of FIG. 1, taken along line A1-A1′ of FIG. 2. FIG. 4 is a schematic enlarged view of a portion of the semiconductor package 1000 of FIG. 2.

Referring to FIGS. 1 to 4, the semiconductor package 1000 may include a package substrate 100, a photonic integrated circuit (PIC) chip 200, an interposer 300, an electronic integrated circuit (EIC) chip 400, and a semiconductor chip 500.

Hereinafter, unless particularly defined otherwise, a direction parallel to an upper surface of the package substrate 100 is defined as a first direction (X direction), a direction perpendicular to the upper surface of the package substrate 100 is defined as a vertical direction (Z direction), and a direction perpendicular to the first direction (X direction) and the vertical direction (Z direction) is defined as a second direction (Y direction). A direction combining the first direction (X direction) and the second direction (Y direction) is defined as a horizontal direction.

In FIG. 3, a dotted arrow indicates a path along which an optical signal PS moves, and a dash-dotted arrow indicates a path along which an electrical signal ES moves. The direction of the dotted arrow and the dash-dotted arrow shown in FIG. 3 may indicate paths through which the optical signal PS and the electrical signal ES are input to the semiconductor package 1000, and paths through which the optical signal PS and the electrical signal ES are output from the semiconductor package 1000 may be in a direction opposite to the direction of the dotted arrow and the dash-dotted arrow shown in FIG. 3.

The package substrate 100 of the semiconductor package 1000 may be, for example, a printed circuit board (PCB). The package substrate 100 may include a first core substrate 110 including at least one material selected from phenol resin, epoxy resin, and polyimide. For example, the first core substrate 110 may include at least one material selected from polyimide, flame retardant 4 (FR-4), tetrafunctional epoxy, polyphenylene ether, epoxy/polyphenylene oxide, bismaleimide triazine (BT), THERMOUNT® (a nonwoven aramid fiber reinforces substrate for printed wiring boards), cyanate ester, and liquid crystal polymer.

The first core substrate 110 of the package substrate 100 may include a groove 100_R. For example, the package substrate 100 may define the groove 100_R as extending from an upper surface of package substrate 100 into the package substrate 100. The groove 100_R may extend inward from an upper surface of the first core substrate 110. The groove 100_R may be in contact with a side surface of the first core substrate 110. For example, in a plan view, the groove 100_R may be in contact with one side of the upper surface of the first core substrate 110. That is, the groove 100_R may be referred to as a notch.

In some example embodiments, the size of the groove 100_R may correspond to the size of the PIC chip 200. In some example embodiments, the depth of the groove 100_R may correspond to the height of the PIC chip 200.

In some example embodiments, FIG. 1 shows that four grooves 100_R are formed on each side of the upper surface of the first core substrate 110, but the number of grooves 100_R corresponds to the number of PIC chips 200 and is not limited thereto.

The package substrate 100 may include an upper pad 170 located on the upper surface of the first core substrate 110 and a lower pad (not shown) located on a lower surface of the first core substrate 110. In some example embodiments, the upper pad 170 and the lower pad may be portions of circuit wirings formed by coating the upper and lower surfaces of the first core substrate 110 with copper (Cu) foil and then patterning the Cu foil. For example, the upper pad 170 and the lower pad may be regions of the circuit wirings, which are not covered by a solder resist layer and are exposed to the outside.

In some example embodiments, the upper pad 170 and the lower pad may each include Cu, nickel (Ni), stainless steel, or beryllium copper (BeCu). Internal wirings may be formed in the package substrate 100 to electrically connect the upper pad 170 and the lower pad to each other.

External connection terminals (not shown) may be attached to the lower pad (not shown). The external connection terminals may be configured to electrically and physically connect the package substrate 100 and an external device, on which the package substrate 100 is mounted, to each other. The external connection terminals may be formed from, for example, solder balls or solder bumps.

The PIC chip 200 of the semiconductor package 1000 may be mounted in the groove 100_R of the package substrate 100. For example, because the groove 100_R is in contact with a side surface of the package substrate 100, one side surface of the PIC chip 200 may not be covered by the first core substrate 110 of the package substrate 100. In some example embodiments, one side surface of the PIC chip 200 may be coplanar with one side surface of the package substrate 100.

In some example embodiments, the PIC chip 200 may be attached to a lower surface of the groove 100_R through an adhesive member 120. For example, the adhesive member 120 may include an adhesive film such as a direct adhesive film (DAF). For example, the PIC chip 200 may not be electrically coupled to the lower surface of the groove 100_R of the package substrate 100.

The PIC chip 200 may input and output the optical signal PS. For example, the PIC chip 200 may convert the electrical signal ES into the optical signal PS and transmit the optical signal PS to an optical fiber 600, and may convert the optical signal PS transmitted from the optical fiber 600 into the electrical signal ES and transmit the electrical signal ES to the EIC chip 400.

The PIC chip 200 may include a first substrate 210, a first wiring structure 230, and an optical-electrical conversion unit 220.

The first substrate 210 may include a semiconductor material such as silicon (Si). Alternatively, the first substrate 210 may include a semiconductor material such as germanium (Ge).

The first substrate 210 may include an active surface 211, on which a plurality of individual devices are formed, and an inactive surface facing the active surface 211. The first wiring structure 230 may be formed on the active surface 211 of the first substrate 210.

The PIC chip 200 may be arranged on the package substrate 100 such that the active surface 211 of the first substrate 210 of the PIC chip 200 faces the semiconductor chip 500. For example, the PIC chip 200 may be arranged on the package substrate 100 in a face-up manner. Herein, the active surface 211 of the first substrate 210 may be referred to as an upper surface of the first substrate 210, and the inactive surface of the first substrate 210 may be referred to as a lower surface of the first substrate 210. However, the vertical position relationship between the active surface 211 and the inactive surface is not limited thereto.

The optical-electrical conversion unit 220 of the PIC chip 200 may convert an optical signal into an electrical signal and convert an electrical signal into an optical signal. In some example embodiments, the optical-electrical conversion unit 220 may include a grid coupler 221, a waveguide 222, a photodetector 223, a laser diode 224, and a modulator 225.

In a process in which the optical signal PS is input to the PIC chip 200, the photodetector 223 may detect the optical signal PS input to the PIC chip 200. The optical signal PS may be detected and converted into the electrical signal ES through the photodetector 223. The electrical signal ES converted by the photodetector 223 may be transmitted to the plurality of individual devices (not shown) on the active surface 211 of the first substrate 210 of the PIC chip 200.

In a process in which the PIC chip 200 outputs the optical signal PS, the plurality of individual devices on the active surface 211 of the first substrate 210 of the PIC chip 200 may transmit the electrical signal ES to the modulator 225. The modulator 225 may input an electrical signal ES to the laser diode 224 which may convert the electrical signal ES into the optical signal PS.

The waveguide 222 may be a path along which the optical signal PS moves in the PIC chip 200. In some example embodiments, the laser diode 224, the modulator 225, and the photodetector 223 may be located on one side of the waveguide 222, and the grid coupler 221 may be located on the other side of the waveguide 222. The waveguide 222 may be a path through which the optical signal PS incident on the grid coupler 221 moves to the photodetector 223 or a path along which the optical signal PS converted by the photodiode 224 moves to the grid coupler 221. For example, the optical signal PS may move along the waveguide 222 in the horizontal direction on an upper surface of the PIC chip 200.

The grid coupler 221 may be a portion of the waveguide 222. For example, the grid coupler 221 may be a region of the waveguide 222, on which the optical signal PS emitted from the optical fiber 600 is incident. The grid coupler 221 may be a region in which the optical signal PS is emitted from the waveguide 222 to the optical fiber 600.

In some example embodiments, the grid coupler 221 may be a region in which a plurality of grid fins protruding upward from the waveguide 222 are located. For example, the plurality of grid fins may be apart from each other in the vertical direction (Z direction) to form a grid structure.

In some example embodiments, the waveguide 222 may be arranged on the groove 100_R of the package substrate 100 such that the grid coupler 221 faces the side surface of the package substrate 100. For example, the grid coupler 221 may be closer to the side surface of the package substrate 100 than the photodiode 224.

In some example embodiments, when a plurality of optical fibers 600 are connected to one PIC chip 200, the optical-electrical conversion unit 220 may include a plurality of grid couplers 221. The plurality of grid couplers 221 may have one-to-one correspondence with the plurality of optical fibers 600. The plurality of optical fibers 600 may face different grid couplers 221. For example, each of the plurality of optical fibers 600 may input/output the optical signal PS to a corresponding one of the plurality of grid couplers 221.

FIG. 3 shows that the optical-electrical conversion unit 220 is buried in a first insulating layer 233, but other example embodiments are not limited thereto. The optical-electrical conversion unit 220 may be covered with an oxide layer that is distinct from the first insulating layer 233. For example, an oxide layer may be formed on one side of the first insulating layer 233, and the optical-electrical conversion unit 220 may be located inside the oxide layer.

The first wiring structure 230 of the PIC chip 200 may include a plurality of first wiring patterns 231, a plurality of first wiring vias 232 connected to the plurality of first wiring patterns 231, and the first insulating layer 233 surrounding the plurality of first wiring patterns 231 and the plurality of first wiring vias 232. In some example embodiments, the first wiring structure 230 may have a multi-layer wiring structure including the first wiring patterns 231 and the first wiring vias 232 located at different vertical levels. Herein, the term “vertical level” refers to a distance apart from a lower surface of the package substrate 100.

In some example embodiments, the PIC chip 200 may further include an upper pad. The upper pad may be arranged on an upper surface of the first wiring structure 230 of the PIC chip 200 and electrically connected to the plurality of first wiring patterns 231 and/or the plurality of first wiring vias 232.

In some example embodiments, the optical fiber 600 may directly input/output the optical signal PS to the grid coupler 221 of the PIC chip 200. For example, the PIC chip 200 may be located below the optical fiber 600 in the vertical direction (Z direction). For example, the optical signal PS emitted from the optical fiber 600 may be incident on the grid coupler 221 of the PIC chip 200 in a direction inclined in the vertical direction (Z direction) with respect to the upper surface of the PIC chip 200.

The interposer 300 of the semiconductor package 1000 may be located above the PIC chip 200 and the package substrate 100. For example, a portion of the interposer 300 may overlap the PIC chip 200 in the vertical direction (Z direction), and another portion of the interposer 300 may overlap the package substrate 100 in the vertical direction (Z direction).

The interposer 300 may include a second core substrate 310 and a first through via 315 penetrating the second core substrate 310. For example, the second core substrate 310 may include glass, and the first through via 315 may be a through glass via (TGV). However, other example embodiments are not limited thereto, and the second core substrate 310 may include Si, and the first through via 315 may be a through silicon via (TSV). In some example embodiments, as shown in FIG. 3, the first through via 315 may be arranged in a two-dimensional array structure in the second core substrate 310, excluding a cavity 300_C of the second core substrate 310.

FIG. 4 shows that the first through via 315 has a constant width, but embodiments are not limited thereto. The width of the first through via 315 may vary away from the package substrate 100.

In some example embodiments, the horizontal width of the first through via 315 may increase near upper and lower surfaces of the second core substrate 310. For example, an externally exposed portion of the first through via 315 may have a relatively large horizontal width. A portion of the first through via 315, of which the horizontal width is increased at the upper surface of the second core substrate 310, may be referred to as an upper pattern 315_U, and a portion of the first through via 315, of which the horizontal width is increased at the lower surface of the second core substrate 310, may be referred to as a lower pattern (e.g., a lower conductive pattern) 315_B.

The second core substrate 310 may include the cavity 300_C. For example, the interposer 300 may define a cavity 300_C extending from an upper surface of the second core substrate 310 to a lower surface of the second core substrate 310. The cavity 300_C may penetrate the second core substrate 310. However, in some example embodiments, the cavity 300_C may have a groove shape in which a portion of the second core substrate 310 is maintained on a bottom surface of the cavity 300_C, without completely penetrating the second core substrate 310.

In FIG. 3, a horizontal cross-section of the cavity 300_C has a quadrangular shape, but the horizontal cross-section of the cavity 300_C is not limited to a quadrangular shape. For example, corresponding to the shape of the EIC chip 400 arranged in the cavity 300_C, the horizontal cross-section of the cavity 300_C may have a polygonal shape other than a circular shape, an elliptical shape, or a quadrangular shape.

In some example embodiments, at least a portion of the cavity 300_C of the interposer 300 may overlap the groove 100_R of the package substrate 100 in the vertical direction. For example, the cavity 300_C of the interposer 300 may have one-to-one correspondence with the groove 100_R of the package substrate.

In some example embodiments, the cavity 300_C of the interposer 300 may be apart from a side surface of the second core substrate 310. However, other example embodiments are not limited thereto, and the cavity 300_C may be in contact with the side surface of the second core substrate 310.

The interposer 300 may further include an upper redistribution structure 330 and a lower redistribution structure 320. The upper redistribution structure 330 may be located on the upper surface of the second core substrate 310 of the interposer 300, and the lower redistribution structure 320 may be located on the lower surface of the second core substrate 310 of the interposer 300.

For example, the upper redistribution structure 330 and the lower redistribution structure 320 may be electrically connected to each other through the first through via 315 and/or the EIC chip 400. In some example embodiments, the electrical signal ES emitted by the PIC chip 200 may pass through the lower redistribution structure 320, the first through via 315, and the upper redistribution structure 330 and be transmitted to the semiconductor chip 500.

The upper redistribution structure 330 may include an upper redistribution line 331, an upper redistribution via 332 vertically extending from the upper redistribution line 331, and an upper insulating layer 333 surrounding the upper redistribution line 331 and the upper redistribution via 332. In some example embodiments, the upper insulating layer 333 may have a shape in which a plurality of layers are stacked.

The lower redistribution structure 320 may include a lower redistribution line 321, a lower redistribution via 322 vertically extending from the lower redistribution line 321, and a lower insulating layer 323 surrounding the lower redistribution line 321 and the lower redistribution via 322. In some example embodiments, the lower insulating layer 323 may have a shape in which a plurality of layers are stacked.

In some example embodiments, the horizontal width of each of the upper redistribution via 332 and the lower redistribution via 322 may vary toward the second core substrate 310. For example, each of the upper redistribution via 332 and the lower redistribution via 322 may have a tapered shape in which the horizontal width thereof narrows toward the second core substrate 310. For example, each of the upper redistribution via 332 and the lower redistribution via 322 may be formed such that the width thereof in the first direction (X direction) and/or the width thereof in the second direction (Y direction) gradually decreases toward the second core substrate 310.

For example, each of the upper insulating layer 333 and the lower insulating layer 323 may include any one material selected from a photo-imageable dielectric (PID), an Ajinomoto Build-up Film® (ABF), a solder resist (SR), an epoxy molding compound (EMC), FR-4, and BT.

In some example embodiments, the upper insulating layer 333 may include thermosetting resin. For example, the upper insulating layer 333 may include an ABF. In some example embodiments, the lower insulating layer 323 may include photosensitive resin. For example, the lower insulating layer 323 may include a PID.

For example, each of the upper redistribution line 331, the upper redistribution via 332, the lower redistribution line 321, and the lower redistribution via 322 may include a metal, such as Cu, aluminum (Al), tungsten (W), titanium (Ti), tantalum (Ta), indium (In), molybdenum (Mo), manganese (Mn), cobalt (Co), tin (Sn), Ni, magnesium (Mg), rhenium (Re), Be, gallium (Ga), or ruthenium (Ru), or an alloy thereof, but embodiments are not limited thereto.

In some example embodiments, the interposer 300 may further include an upper pad 370 and a lower pad 380. The upper pad 370 may be located above the upper redistribution structure 330, and the lower pad 380 may be located below the lower redistribution structure 320. For example, the upper pad 370 of the interposer 300 may be electrically connected to the upper redistribution line 331 and/or the upper redistribution via 332, and the lower pad 380 of the interposer 300 may be electrically connected to the lower redistribution line 321 and/or the lower redistribution via 322.

In some example embodiments, the lower pad 380 of the interposer 300 may be electrically connected to the upper pad 170 of the package substrate 100 or the upper pad of the PIC chip 200 through a connection terminal CT3.

The EIC chip 400 of the semiconductor package 1000 may be arranged inside the interposer 300. For example, the EIC chip 400 may be arranged in the cavity 300_C of the interposer 300.

In some example embodiments, the EIC chip 400 may overlap the PIC chip 200 in the vertical direction. For example, the EIC chip 400 may be located above the lower redistribution structure 320 and electrically connected to the PIC chip 200 through the lower redistribution structure 320. By reducing a signal distance between the EIC chip 400 and the PIC chip 200, signal characteristics may be improved.

In some example embodiments, the EIC chip 400 may have one-to-one correspondence with the PIC chip 200. For example, one EIC chip 400 may be located above one PIC chip 200 corresponding thereto.

The EIC chip 400 may include a second substrate 410, a second wiring structure 420, and a second through via 415. The second substrate 410 of the EIC chip 400 may include an active surface 411 and an inactive surface facing the active surface 411. The second wiring structure 420 may be formed on the active surface 411 of the second substrate 410. The second through via 415 may extend from the inactive surface of the second substrate 410 to the active surface 411 of the second substrate 410. In some example embodiments, the second through via 415 may be electrically connected to the second wiring structure 420 and/or a plurality of individual devices on the active surface 411.

In some example embodiments, the EIC chip 400 may be arranged inside the interposer 300 such that the active surface 411 of the second substrate 410 faces the PIC chip 200. For example, the EIC chip 400 may be arranged inside the interposer 300 in a face-down manner. However, other example embodiments are not limited thereto, and the EIC chip 400 may be arranged inside the interposer 300 in a face-up manner.

The second substrate 410 may include a semiconductor material such as Si. Alternatively, the second substrate 410 may include a semiconductor material such as Ge.

In some example embodiments, the EIC chip 400 may include a plurality of individual devices used by the PIC chip 200 to interface with other individual devices. The plurality of individual devices of the EIC chip 400 may be located on the active surface 411 of the second substrate 410. For example, the EIC chip 400 may include complementary metal-oxide semiconductor (CMOS) drivers, transimpedance amplifiers, and the like to perform functions such as a function for controlling high-frequency signaling of the PIC chip 200.

The second wiring structure 420 of the EIC chip 400 may include a plurality of second wiring patterns 421, a plurality of second wiring vias 422 connected to the plurality of second wiring patterns 421, and a second insulating layer 423 surrounding the plurality of second wiring patterns 421 and the plurality of second wiring vias 422. In some example embodiments, the second wiring structure 420 may have a multi-layer wiring structure including the second wiring patterns 421 and the second wiring vias 422 located at different vertical levels.

In some example embodiments, the EIC chip 400 may further include an upper pad 470. The upper pad 470 may be arranged on an upper surface of the EIC chip 400 and electrically connected to the second through via 415.

In some example embodiments, the upper pad 470 of the EIC chip 400 may be electrically connected to the upper redistribution line 331 and/or the upper redistribution via 332 of the upper redistribution structure 330 of the interposer 300.

In some example embodiments, the EIC chip 400 may further include a lower pad 480. The lower pad 480 may be arranged on a lower surface of the EIC chip 400 and electrically connected to the second wiring pattern 421 and/or the second wiring via 422.

In some example embodiments, the lower pad 480 of the EIC chip 400 may be electrically connected to the lower redistribution line 321 and/or the lower redistribution via 322 of the lower redistribution structure 320 of the interposer 300. For example, the lower pad 480 of the EIC chip 400 may be in direct contact with the lower redistribution line 321 of the lower redistribution structure 320.

In some example embodiments, a vertical level of the lower surface of the EIC chip 400 may be substantially the same as a vertical level of the lower surface of the second core substrate 310 of the interposer 300. For example, a vertical level VL_480 of the lower pad 480 of the EIC chip 400 may be the same as a vertical level VL_315 of the lower pattern 315_B of the first through via 315 of the interposer 300.

The EIC chip 400 and the second core substrate 310 of the interposer 300 may be located above the lower redistribution structure 320, and the lower pad 480 of the EIC chip 400 and the first through via 315 of the interposer 300 may be electrically connected to the lower redistribution structure 320. Accordingly, a lower surface of the lower pad 480 of the EIC chip 400 may be coplanar with a lower surface of the lower pattern 315_B of the first through via 315 of the interposer 300.

For example, by mounting the EIC chip 400 in the cavity 300_C of the second core substrate 310 of the interposer 300 and then forming the lower redistribution structure 320, the vertical level of the lower surface of the EIC chip 400 may be substantially the same as the vertical level of the lower surface of the second core substrate 310 of the interposer 300.

The upper pad 470 of the EIC chip 400 may be electrically connected to the upper redistribution line 331 and/or the upper redistribution via 332 of the upper redistribution structure 330.

The semiconductor chip 500 of the semiconductor package 1000 may be located above the interposer 300. For example, the semiconductor chip 500 may be arranged on the upper redistribution structure 330 of the interposer 300. In some example embodiments, the semiconductor chip 500 may be apart from the PIC chip 200 with the interposer 300 therebetween.

In some example embodiments, by extending the interposer 300 to the outside of an active surface 511 of a third substrate 510 of the semiconductor chip 500, a region in which a signal terminal is arranged may be expanded. For example, the semiconductor package 1000 may have a fan-out wafer level package (FO-WLP) or fan-out panel level package (FO-PLP) (hereinafter, collectively referred to as FO-WLP) structure.

The semiconductor chip 500 may include the third substrate 510 and a third wiring structure 520. The third substrate 510 may include the active surface 511 and an inactive surface facing the active surface 511. The third wiring structure 520 may be formed on the active surface 511 of the third substrate 510. In some example embodiments, the semiconductor chip 500 may include an application-specific integrated circuit (ASIC).

In some example embodiments, a plurality of individual devices of various types may be located on the active surface 511 of the third substrate 510 of the semiconductor chip 500. For example, the plurality of individual devices may include various microelectronic devices, for example, a CMOS transistor, a metal-oxide-semiconductor field-effect transistor (MOSFET), system large-scale integration (LSI), an image sensor such as a CMOS imaging sensor (CIS), a micro-electro-mechanical system (MEMS), an active device, a passive device, and the like.

In some example embodiments, the semiconductor chip 500 may be arranged on the interposer 300 such that the active surface 511 of the third substrate 510 faces the interposer 300. For example, the semiconductor chip 500 may be arranged on the interposer 300 in a face-down manner. However, other example embodiments are not limited thereto, and the semiconductor chip 500 may be arranged on the interposer 300 in a face-up manner.

The third wiring structure 520 of the semiconductor chip 500 may include a plurality of third wiring patterns 521, a plurality of third wiring vias 522 connected to the plurality of third wiring patterns 521, and a third insulating layer 523 surrounding the plurality of third wiring patterns 521 and the plurality of third wiring vias 522. In some example embodiments, the third wiring structure 520 may have a multi-layer wiring structure including the third wiring patterns 521 and the third wiring vias 522 located at different vertical levels.

In some example embodiments, a lower pad 580 of the semiconductor chip 500 may be electrically connected to the upper pad 370 of the interposer 300 through a connection terminal CT5. However, a method of connecting the semiconductor chip 500 and the interposer 300 to each other is not limited thereto.

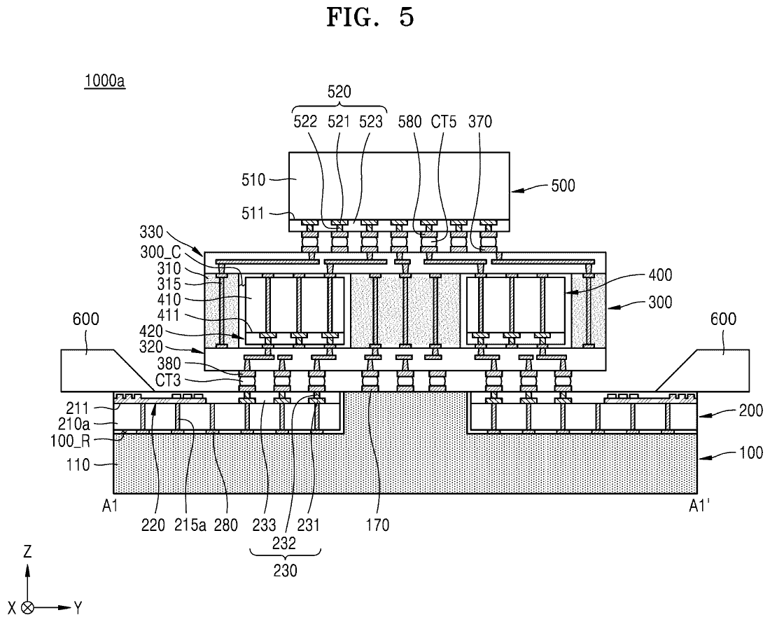

FIG. 5 is a schematic cross-sectional view of a semiconductor package 1000a according to some example embodiments, taken along line A1-A1′ of FIG. 2.

Most of components constituting the semiconductor package 1000a described below and materials constituting the components are substantially the same as or similar to those described above with reference to FIG. 1. Accordingly, for convenience of description, differences between the semiconductor package 1000a of FIG. 5 and the semiconductor package 1000 of FIG. 1 described above will be mainly described.

The PIC chip 200 of the semiconductor package 1000a may further include a third through via 215a. The third through via 215a may penetrate a first substrate 210a of the PIC chip 200. The third through via 215a may extend from an active surface of the first substrate 210a to an inactive surface of the first substrate 210a. In some example embodiments, the third through via 215a may be electrically connected to the first wiring structure 230 and/or a plurality of individual devices on the active surface of the first substrate 210a. In some example embodiments, the horizontal width of the third through via 215a may vary as the third through via 215a extends from the active surface of the first substrate 210a to the inactive surface of the first substrate 210a.

The PIC chip 200 may further include a lower pad 280. The lower pad 280 may be arranged on a lower surface of the PIC chip 200 and electrically connected to the third through via 215a. The lower pad 280 may be electrically connected to the package substrate 100. For example, the lower pad 280 may be electrically connected to a circuit wiring of the package substrate 100 through a connection terminal. In some example embodiments, an underfill layer surrounding the lower pad 280 of the PIC chip 200 may be further included.

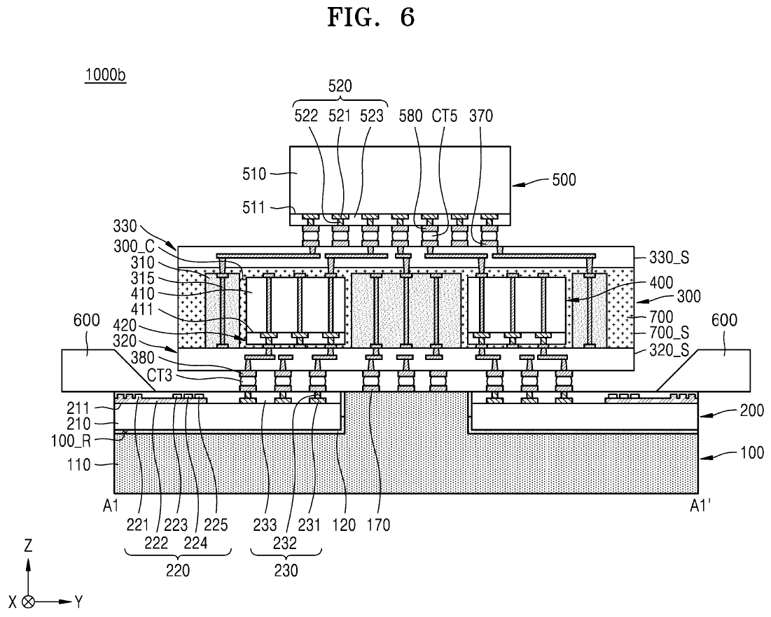

FIG. 6 is a schematic cross-sectional view of a semiconductor package 1000b according to some example embodiments, taken along line A1-A1′ of FIG. 2.

Most of components constituting the semiconductor package 1000b described below and materials constituting the components are substantially the same as or similar to those described above with reference to FIG. 1. Accordingly, for convenience of description, differences between the semiconductor package 1000b of FIG. 6 and the semiconductor package 1000 of FIG. 1 described above will be mainly described.

The interposer 300 of the semiconductor package 1000b may further include a scaling layer 700. The scaling layer 700 may surround the side surface of the second core substrate 310 of the interposer 300 and the EIC chip 400. In some example embodiments, the sealing layer 700 may surround all corners of the second core substrate 310.

In some example embodiments, the sealing layer 700 may fill the inside of the cavity 300_C of the second core substrate 310 and cover the upper and side surfaces of the second core substrate 310. For example, the second core substrate 310 and the EIC chip 400 may be buried inside the sealing layer 700.

The upper redistribution structure 330 described above may be located on an upper surface of the sealing layer 700, and the lower redistribution structure 320 described above may be located on a lower surface of the sealing layer 700. For example, the sealing layer 700 may be located between the upper redistribution structure 330 and the lower redistribution structure 320.

In some example embodiments, a side surface 700_S of the sealing layer 700, a side surface 330_S of the upper redistribution structure 330, and a side surface 320_S of the lower redistribution structure 320 may be coplanar with each other. For example, the horizontal area of the sealing layer 700, the horizontal area of the upper redistribution structure 330, and the horizontal area of the lower redistribution structure 320 may be the same as each other.

For example, the upper redistribution via 332 (of FIG. 4) of the upper redistribution structure 330 may penetrate a portion of the sealing layer 700 and be electrically connected to the first through via 315 of the second core substrate 310 or the upper pad 470 (of FIG. 4) of the EIC chip 400.

For example, the sealing layer 700 may include an organic material containing a filler. In some example embodiments, the sealing layer 700 may include any one material selected from a PID, an ABF, an SR, an EMC, FR-4, and BT. For example, the sealing layer 700 may include an ABF, which is thermosetting resin.

Because an outer edge of the second core substrate 310 is surrounded by the sealing layer 700, the second core substrate 310 may be limited and/or prevented from being damaged due to an external impact.

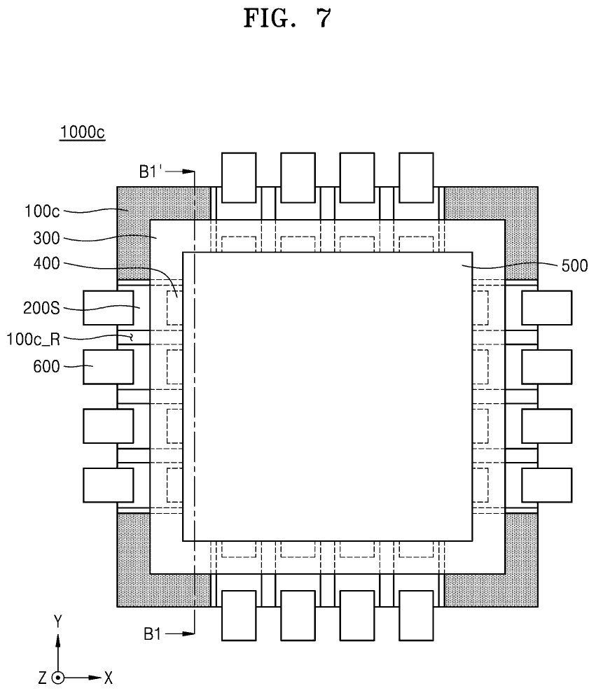

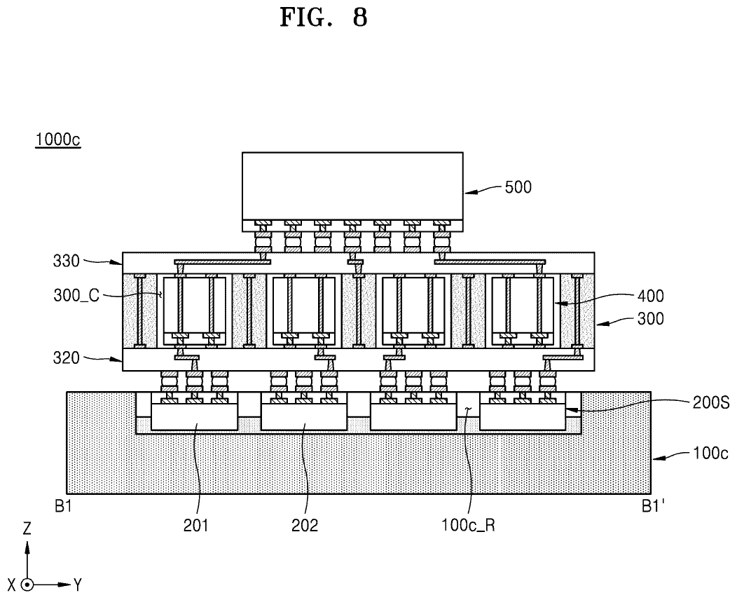

FIG. 7 is a schematic plan view of a semiconductor package 1000c according to some example embodiments. FIG. 8 is a schematic cross-sectional view of the semiconductor package 1000c of FIG. 7, taken along line B1-B1′ of FIG. 7.

Most of components constituting the semiconductor package 1000c described below and materials constituting the components are substantially the same as or similar to those described above with reference to FIG. 1. Accordingly, for convenience of description, differences between the semiconductor package 1000c of FIG. 7 and the semiconductor package 1000 of FIG. 1 described above will be mainly described.

At least one PIC chip 200S may be mounted in a recess 100c_R of a package substrate 100c of the semiconductor package 1000c. For example, the at least one PIC chip 200S may include a first PIC chip 201 and a second PIC chip 202. The first PIC chip 201 and the second PIC chip 202 may be located in one recess 100c_R. FIG. 8 shows that four PIC chips 200S are located in one recess 100c_R, but the number of PIC chips 200S is not limited thereto.

In some example embodiments, the interposer 300 may include at least one cavity 300_C arranged in a line along one side surface of the second core substrate 310 (of FIG. 3). The at least one cavity 300_C may include a first cavity and a second cavity. One of at least one recess 100c_R of the package substrate 100c may overlap at least a portion of the first cavity and at least a portion of the second cavity in the vertical direction (Z direction). For example, a plurality of cavities 300_C of the interposer 300 may be located above one of at least one recess 100c_R of the package substrate 100c.

In some example embodiments, a plurality of EIC chips 400 may be located above one of the at least one recess 100c_R of the package substrate 100c. For example, the EIC chips 400 may be located above the one of the at least one recess 100c_R to correspond to the number of PIC chips 200S arranged inside the recess 100c_R.

Because a separation distance between the plurality of PIC chips 200S is reduced, the size of the semiconductor package 1000c may be reduced.

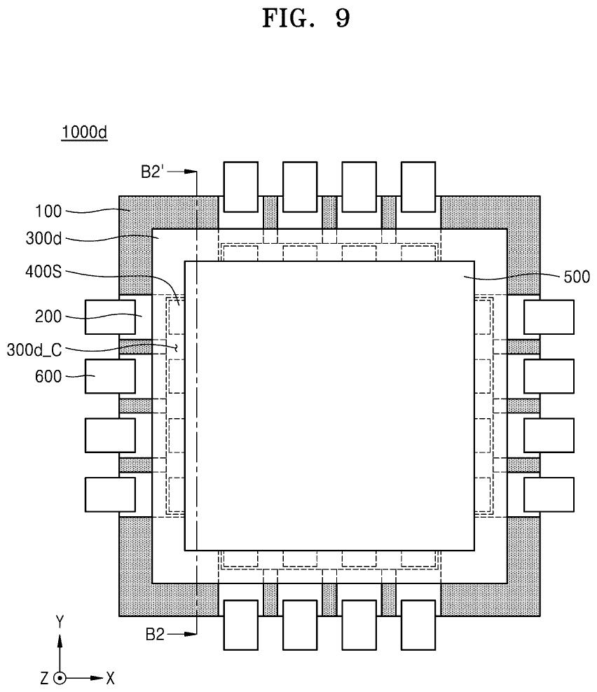

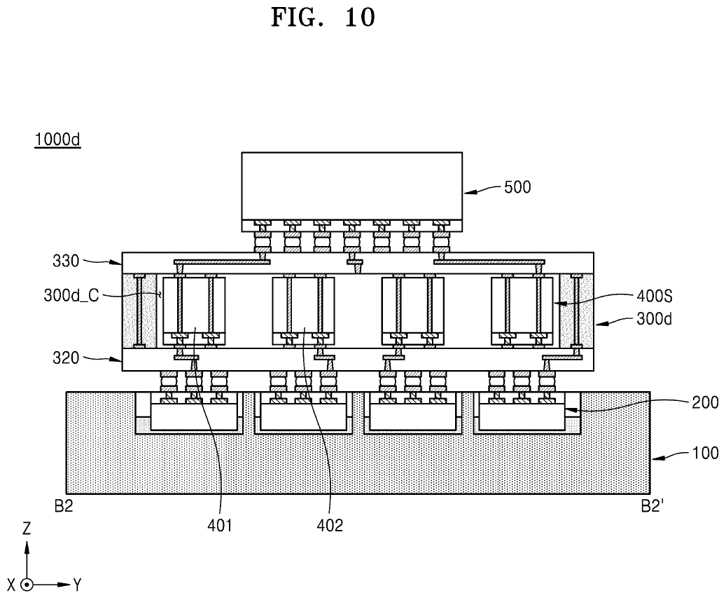

FIG. 9 is a schematic plan view of a semiconductor package 1000d according to some example embodiments. FIG. 10 is a schematic cross-sectional view of the semiconductor package 1000d of FIG. 9, taken along line B2-B2′ of FIG. 9.

Most of components constituting the semiconductor package 1000d described below and materials constituting the components are substantially the same as or similar to those described above with reference to FIG. 1. Accordingly, for convenience of description, differences between the semiconductor package 1000d of FIG. 9 and the semiconductor package 1000 of FIG. 1 described above will be mainly described.

The semiconductor package 1000d may include at least one EIC chip 400S. In some example embodiments, the at least one EIC chip 400S may be arranged in a line inside an interposer 300d, along one side surface of the interposer 300d.

The at least one EIC chip 400S may be mounted inside a cavity 300d_C of the interposer 300d. For example, the at least one EIC chip 400S may include a first EIC chip 401 and a second EIC chip 402. The first EIC chip 401 and the second EIC chip 402 may be mounted inside one cavity 300d_C. FIG. 10 shows that four EIC chips 400S are mounted inside one cavity 300d_C, but the number of EIC chips 400S is not limited thereto.

In some example embodiments, the package substrate 100 may include at least one groove 100_R (of FIG. 3) arranged in a line along one side surface of the first core substrate 110 (of FIG. 3). For example, the at least one groove 100_R may include a first groove and a second groove. At least a portion of the first groove and at least a portion of the second groove may overlap one of the cavities 300d_C of the interposer 300d in the vertical direction.

In some example embodiments, a plurality of PIC chips 200 may be located below one of at least one cavity 300d_C of the interposer 300d in the vertical direction (Z direction). For example, the PIC chips 200 and the grooves 100_R (of FIG. 3), in which the PIC chips 200 are mounted, may be located below the at least one cavity 300d_C to correspond to the number of EIC chips 400S mounted inside the at least one cavity 300d_C.

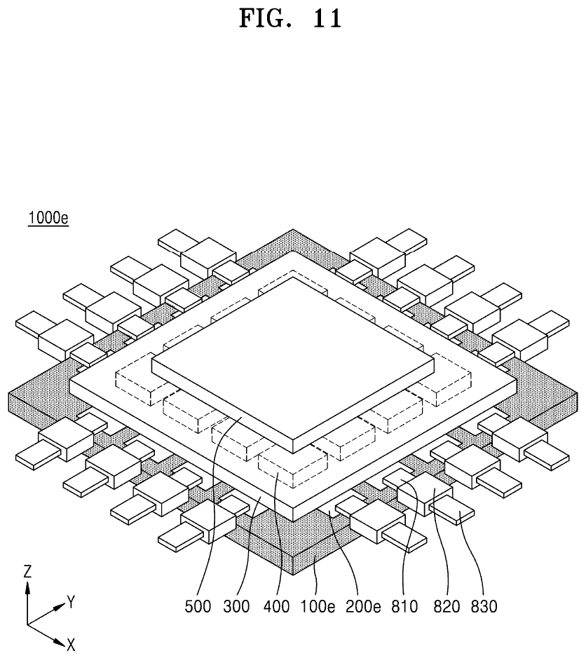

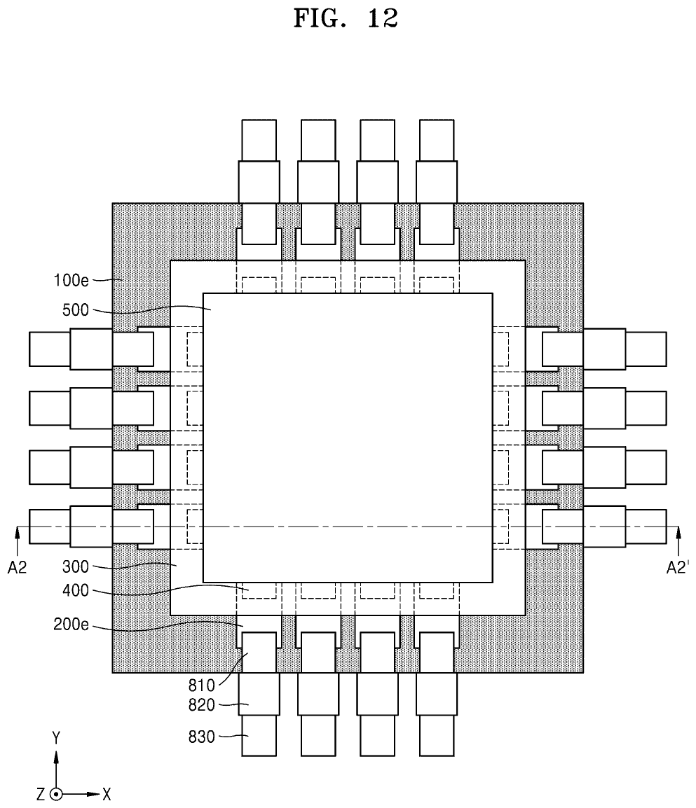

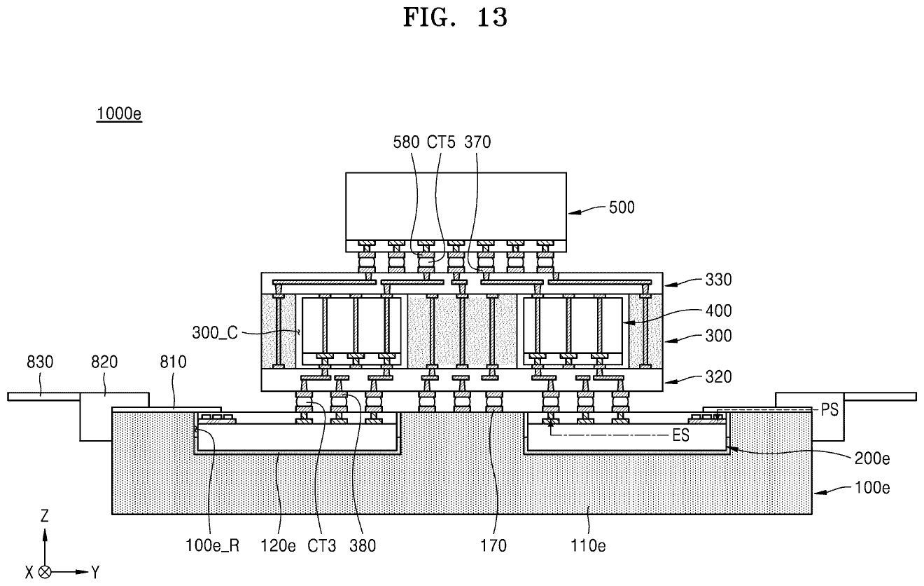

FIG. 11 is a schematic perspective view of a semiconductor package 1000e according to some example embodiments. FIG. 12 is a schematic plan view of the semiconductor package 1000e of FIG. 11. FIG. 13 is a schematic cross-sectional view of the semiconductor package 1000e of FIG. 11, taken along line A2-A2′ of FIG. 12.

Most of components constituting the semiconductor package 1000e described below and materials constituting the components are substantially the same as or similar to those described above with reference to FIG. 1. Accordingly, for convenience of description, differences between the semiconductor package 1000e of FIG. 11 and the semiconductor package 1000 of FIG. 1 described above will be mainly described.

A groove 100e_R of a package substrate 100e of the semiconductor package 1000e may be apart from a side surface of a first core substrate 110e of the package substrate 100e. For example, a sidewall of the first core substrate 110e forming the groove 100e_R may be apart from a side of an upper surface of the first core substrate 110c.

In some example embodiments, an adhesive member 120e that secures the package substrate 100e and a PIC chip 200e to each other may surround the PIC chip 200e. For example, the adhesive member 120e may be surrounded by the first core substrate 110e forming the groove 100e_R and may not be exposed to the outside.

The semiconductor package 1000e may further include an optical fiber 830, a socket 820, and an optical waveguide 810.

The optical waveguide 810 of the semiconductor package 1000e may be attached to an upper surface of the package substrate 100e. For example, the optical waveguide 810 may extend from one corner of the upper surface of the package substrate 100e toward the groove 100e_R. The optical waveguide 810 may extend from the upper surface of the package substrate 100e to an upper portion of the groove 100e_R of the package substrate 100e. For example, one end of the optical waveguide 810 may be connected to the socket 820, and the other end of the optical waveguide 810 may be located above the PIC chip 200c.

In some example embodiments, a portion of the optical waveguide 810 may be located below the interposer 300 in the vertical direction (Z direction). That is, a portion of the optical waveguide 810 may be located between the interposer 300 and the PIC chip 200e. Because the PIC chip 200e is located below the interposer 300, a portion of the optical waveguide 810, which is located above the PIC chip 200e, may be located below the interposer 300.

In some example embodiments, optical waveguide 810 may include a core and cladding surrounding the core. The core may have a relatively high refractive index, and the cladding may have a relatively low refractive index. The optical signal PS incident on the core may proceed along the core having a high refractive index. For example, the optical signal PS traveling from the core to the cladding may be totally reflected and travel along the core, due to a difference in refractive index between the core and the cladding. In some example embodiments, the optical waveguide 810 may be a glass waveguide.

For example, the optical fiber 830 may be connected to the socket 820 and cause the optical signal PS to be incident on the core of the optical waveguide 810. The optical signal PS incident on the core of the optical waveguide 810 may be totally reflected at an interface between the core and the cladding and move along the core. The optical signal PS moving along the optical waveguide 810 may be emitted from the optical waveguide 810 and incident on the PIC chip 200c.

In some example embodiments, an optical-electrical conversion unit of the PIC chip 200e may receive the optical signal PS. For example, a coupler, which is a region in which the optical signal PS is incident on and/or emitted from the optical-electrical conversion unit, may be an edge coupler or a grid coupler. For example, when the optical-electrical conversion unit includes an edge coupler, the edge coupler and the optical waveguide 810 may be at substantially the same vertical level. For example, when the optical-electrical conversion unit includes a grid coupler, the optical waveguide 810 may be located above the grid coupler in the vertical direction (Z direction).

The semiconductor package 1000e including the optical waveguide 810 may improve the accuracy of optical signal transmission in a process of inputting/outputting the optical signal PS from the optical fiber 830 to the PIC chip 200e.

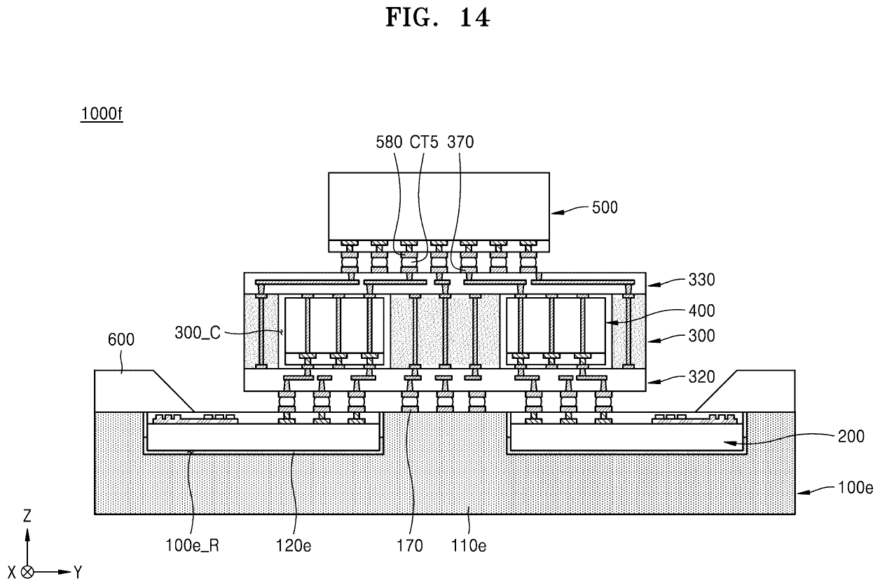

FIG. 14 is a schematic cross-sectional view of a semiconductor package 1000f according to some example embodiments.

Most of components constituting the semiconductor package 1000f described below and materials constituting the components are substantially the same as or similar to those described above with reference to FIG. 1. Accordingly, for convenience of description, differences between the semiconductor package 1000f of FIG. 14 and the semiconductor package 1000e of FIG. 11 described above will be mainly described.

The optical fiber 600 of the semiconductor package 1000f may be located above the first core substrate 110e of the package substrate 100e. For example, the optical fiber 600 may extend from an outer edge of the package substrate 100e to an upper portion of the groove 100e_R of the package substrate 100e. Unlike the semiconductor package 1000e of FIG. 13, in the semiconductor package 1000f of FIG. 14, an optical signal may be transmitted from the optical fiber 600 to the PIC chip 200 without passing through the optical waveguide 810 (of FIG. 13).

The groove 100e_R of the package substrate 100e may be apart from one side surface of the first core substrate 110e. For example, the optical fiber 600 may be located on the upper surface of the first core substrate 110e, which is located between the groove 100e_R and the side surface of the first core substrate 110e.

In some example embodiments, the semiconductor package 1000f may further include a reflective portion (not shown). The reflective portion may include a V-groove, into which the optical fiber 600 is inserted, and a plurality of mirrors. The plurality of mirrors may be arranged such that an optical signal emitted from the optical fiber 600 is reflected according to the law of incidence/reflection and reaches the PIC chip 200. For example, the reflective portion may be located between the groove 100e_R and the side surface of the first core substrate 110e.

In some example embodiments, the PIC chip 200 may include the grid coupler described with respect to FIG. 3. For example, a portion of the optical fiber 600 may be located above the PIC chip 200 so that an optical signal emitted from the optical fiber 600 is incident on the grid coupler.

While the inventive concepts have been particularly shown and described with reference to example embodiments thereof, it will be understood that various changes in form and details may be made therein without departing from the spirit and scope of the following claims.

What is claimed is:

1. A semiconductor package comprising:
a package substrate defining a groove extending from an upper surface of the package substrate into the package substrate;
a photonic integrated circuit (PIC) chip inside the groove of the package substrate;
an interposer above the PIC chip and the package substrate, the interposer comprising a core substrate;
an electronic integrated circuit (EIC) chip inside the interposer; and
a semiconductor chip above the interposer,
wherein the interposer defines a cavity extending from an upper surface of the core substrate to a lower surface of the core substrate, and
the EIC chip is inside the cavity of the core substrate.

2. The semiconductor package of claim 1, wherein the interposer further comprises:
an upper redistribution structure on the upper surface of the core substrate; and
a lower redistribution structure on the lower surface of the core substrate.

3. The semiconductor package of claim 2, wherein a vertical level of a lower conductive pattern on the lower surface of the core substrate is a same as a vertical level of a lower pad on a lower surface of the EIC chip.

4. The semiconductor package of claim 3, wherein
the EIC chip further comprises a through via, and
the upper redistribution structure is electrically connected to the lower redistribution structure through the through via of the EIC chip.

5. The semiconductor package of claim 1, wherein at least a portion of the cavity of the interposer overlaps the groove of the package substrate in a vertical direction.

6. The semiconductor package of claim 1, wherein
the EIC chip comprises an active surface and an inactive surface facing the active surface, and
the active surface of the EIC chip faces the PIC chip.

7. The semiconductor package of claim 1, wherein the EIC chip overlaps the PIC chip in a vertical direction.

8. The semiconductor package of claim 1, wherein
the interposer further comprises a sealing layer, and
the sealing layer surrounds the EIC chip and a side surface of the core substrate of the interposer.

9. The semiconductor package of claim 8, wherein
the interposer further comprises an upper redistribution structure and a lower redistribution structure,
the upper redistribution structure is on an upper surface of the sealing layer,
the lower redistribution structure is on a lower surface of the sealing layer, and
a side surface of the upper redistribution structure, a side surface of the lower redistribution structure, and a side surface of the sealing layer are coplanar.

10. The semiconductor package of claim 1, wherein
the PIC chip comprises a grid coupler configured to transmit and receive optical signals,
the groove of the package substrate extends inward from a side surface of the package substrate, and
an optical fiber configured to transmit and receive the optical signals to and from the grid coupler, and the optical fiber is above the PIC chip.

11. The semiconductor package of claim 1, wherein
the groove of the package substrate is spaced apart from a side surface of the package substrate, and
the semiconductor package further comprises an optical waveguide extending to an upper portion of the groove along the upper surface of the package substrate.

12. The semiconductor package of claim 1, wherein
a material constituting the core substrate comprises glass, and
the interposer further comprises a through via penetrating the core substrate.

13. A semiconductor package comprising:
a package substrate defining at least one groove extending from an upper surface of the package substrate into the package substrate;
at least one photonic integrated circuit (PIC) chip inside the at least one groove of the package substrate;
an interposer above the at least one PIC chip and the package substrate, the interposer comprising a core substrate;
at least one electronic integrated circuit (EIC) chip inside the interposer; and
a semiconductor chip above the interposer,
wherein the interposer defines at least one cavity extending from an upper surface of the core substrate to a lower surface of the core substrate, and
the at least one EIC chip is inside the at least one cavity of the core substrate.

14. The semiconductor package of claim 13, wherein PIC chips from among the at least one PIC chip and EIC chips from among the at least one EIC chip have one-to-one correspondence with each other.

15. The semiconductor package of claim 13, wherein
the interposer further comprises a lower redistribution structure on the lower surface of the core substrate, and
a PIC chip from among the at least one PIC chip and a corresponding EIC chip from among the at least one EIC chip overlap each other in a vertical direction and are electrically connected to each other through the lower redistribution structure.

16. The semiconductor package of claim 13, wherein
the at least one groove of the package substrate comprises a first groove and a second groove, and
at least a portion of the first groove and at least a portion of the second groove are below a cavity from among the at least one cavity of the interposer.

17. The semiconductor package of claim 13, wherein
the at least one cavity of the interposer comprises a first cavity and a second cavity, and
at least a portion of the first cavity and at least a portion of the second cavity are above a groove from among the at least one groove of the package substrate.

18. A semiconductor package comprising:
a package substrate defining a groove extending from an upper surface of the package substrate into the package substrate;
a photonic integrated circuit (PIC) chip inside the groove of the package substrate, the PIC chip comprising an optical-electrical conversion unit;
an interposer above the PIC chip and the package substrate, the interposer comprising a core substrate, an upper redistribution structure, and a lower redistribution structure, the upper redistribution structure being on an upper surface of the core substrate, and the lower redistribution structure being on a lower surface of the core substrate;
an electronic integrated circuit (EIC) chip inside the interposer, the EIC chip comprising a substrate and a through via, the substrate having an active surface and an inactive surface facing the active surface, and the through via extending from the inactive surface of the substrate to the active surface of the substrate; and
a semiconductor chip above the interposer,
wherein the interposer defines a cavity extending from the upper surface of the core substrate to the lower surface of the core substrate, and
the EIC chip is inside the cavity of the core substrate, and the active surface of the substrate of the EIC chip faces the PIC chip.

19. The semiconductor package of claim 18, wherein
the cavity of the interposer is above the groove of the package substrate, and
the EIC chip overlaps the PIC chip in a vertical direction.

20. The semiconductor package of claim 18, wherein
the interposer further comprises a sealing layer between the lower redistribution structure and the upper redistribution structure, and the sealing layer surrounds a side surface of the core substrate of the interposer, and
the sealing layer surrounds the EIC chip.
